(19) United States
(12) Patent Application Publication
(10) Pub. No.: US 2026/0246434 A1
(43) Pub. Date: Aug. 20, 2026

(54) AMPLIFIER DEVICE AND POWER SUPPLY DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: Masaya KONDO, Nisshin-shi (JP); Masaru NAGAO, Nisshin-shi (JP); Yoshikazu FURUTA, Nisshin-shi (JP); Tomohiro NEZUKA, Nisshin-shi (JP)

(21) Appl. No.: 19/447,040

(22) Filed: Jan. 13, 2026

(30) Foreign Application Priority Data
Feb. 19, 2025 (JP) 2025-024973

(51) Int. Cl. H03F 3/45; H03F 1/26

(52) U.S. Cl. CPC H03F 3/45219; H03F 1/26; H03F 2200/121; H03F 2200/171; H03F 2200/271; H03F 2200/459

(57) ABSTRACT

An amplifier device includes a chopper amplifier and a ripple attenuation loop. The chopper amplifier includes a first chopper circuit and a second chopper circuit that perform chopping in response to a first clock signal, a first transconductance amplifier, a converter, and a low-pass filter. The ripple attenuation loop includes a high-pass filter, a third chopper circuit, a fourth chopper circuit and a fifth chopper circuit that perform chopping in response to a second clock signal different from the first clock signal, a second transconductance amplifier, and a third transconductance amplifier. A pair of output signals output from the third transconductance amplifier are coupled to a pair of output signals output from the first transconductance amplifier, respectively.

### CROSS REFERENCE TO RELATED APPLICATION

This application is based on Japanese Patent Application No. 2025-024973 filed on Feb. 19, 2025, the disclosure of which is incorporated herein by reference.

### TECHNICAL FIELD

The present disclosure relates to an amplifier device and a power supply device.

### BACKGROUND

There may be some techniques for suppressing ripple generated by a chopping operation in a chopper amplifier. A chopper-stabilized amplifier may include a main signal path and an automatic correction feedback loop.

### SUMMARY

According to an aspect of the present disclosure, an amplifier device includes a chopper amplifier, a ripple attenuation loop, and a low-pass filter. The chopper amplifier has a pair of input terminals and an output terminal. The ripple attenuation loop is connected to the output terminal. The chopper amplifier includes a first chopper circuit, a first transconductance amplifier, a second chopper circuit, and a converter. The first chopper circuit chops a pair of input signals received from the pair of input terminals according to a first clock signal, and outputs a pair of output signals. The first transconductance amplifier receives the pair of output signals from the first chopper circuit, and outputs a pair of differential output signals. The second chopper circuit chops the pair of differential output signals received from the first transconductance amplifier according to the first clock signal, and outputs a pair of output signals. The converter receives the pair of output signals from the second chopper circuit as differential input signals, converts the received pair of output signals to a single-ended signal, and outputs the single-ended signal. The ripple attenuation loop includes a high-pass filter, a third chopper circuit, a fourth chopper circuit, a second transconductance amplifier, a fifth chopper circuit, a first capacitor, and a third transconductance amplifier. The high-pass filter receives the single-ended signal, and outputs an output signal. The third chopper circuit chops the output signal received from the high-pass filter and a reference voltage according to the first clock signal and outputs a pair of output signals. The fourth chopper circuit chops the pair of output signals received from the third chopper circuit according to a second clock signal different from the first clock signal and outputs a pair of output signals. The second transconductance amplifier receives the pair of output signals from the fourth chopper circuit and outputs a pair of differential output signals. The fifth chopper circuit has a pair of output terminals. The fifth chopper circuit chops the pair of differential output signals received from the second transconductance amplifier according to the second clock signal, and outputs a pair of output signals from the pair of output terminals. The first capacitor is connected between the pair of output terminals of the fifth chopper circuit. The third transconductance amplifier may receive the pair of output signals from the fifth chopper circuit, and output a pair of differential output signals. The low-pass filter may suppress ripple in the single-ended signal. The pair of differential output signals from the third transconductance amplifier may be coupled to the pair of differential output signals from the first transconductance amplifier, respectively.

### BRIEF DESCRIPTION OF DRAWINGS

FIG. 1 is a circuit diagram that illustrates an amplifier device.

FIG. 2 is a circuit diagram that illustrates a first chopper circuit.

FIG. 3 is a timing chart of clock signals.

FIG. 4 is a circuit diagram that illustrates a main signal path.

FIG. 5 is a circuit diagram that illustrates a ripple attenuation loop.

FIG. 6 is a first timing chart for each node.

FIG. 7 is a second timing chart for each node.

FIG. 8 is a diagram illustrating a method for setting a high-pass filter.

FIG. 9 is a third timing chart for each node.

FIG. 10 is a circuit diagram that illustrates a power supply device.

FIG. 11 is a diagram that illustrates a chopper amplifier according to another embodiment.

FIG. 12 is a diagram that illustrates a third transconductance amplifier according to another embodiment.

FIG. 13 is a diagram that illustrates each filter according to another embodiment.

FIG. 14 is a diagram that illustrates a buffer circuit according to another embodiment.

FIG. 15 is a diagram that illustrates a buffer circuit in a power supply device according to another embodiment.

### DETAILED DESCRIPTION

A chopper-stabilized amplifier includes a main signal path and an automatic correction feedback loop. The automatic correction feedback loop may include an additional transconductance amplifier, an additional chopping circuit, a filter, and a further transconductance amplifier in order to suppress ripple.

However, in the chopper-stabilized amplifier described above, there is a possibility that, for example, the input offset voltage of the further transconductance amplifier in the automatic correction feedback loop may remain as an error in the output.

According to a first aspect of the present disclosure, an amplifier device includes a chopper amplifier, a ripple attenuation loop, and a low-pass filter. The chopper amplifier has a pair of input terminals and an output terminal. The ripple attenuation loop is connected to the output terminal. The chopper amplifier includes a first chopper circuit, a first transconductance amplifier, a second chopper circuit, and a converter. The first chopper circuit chops a pair of input signals received from the pair of input terminals according to a first clock signal, and outputs a pair of output signals. The first transconductance amplifier receives the pair of output signals from the first chopper circuit, and outputs a pair of differential output signals. The second chopper circuit chops the pair of differential output signals received from the first transconductance amplifier according to the first clock signal and outputs a pair of output signals. The converter receives the pair of output signals from the second chopper circuit as differential input signals, converts the received pair of output signals to a single-ended signal, and outputs the single-ended signal. The ripple attenuation loop includes a high-pass filter, a third chopper circuit, a fourth chopper circuit, a second transconductance amplifier, a fifth chopper circuit, a first capacitor, and a third transconductance amplifier. The high-pass filter receives the single-ended signal and outputs an output signal. The third chopper circuit chops the output signal received from the high-pass filter and a reference voltage according to the first clock signal and outputs a pair of output signals. The fourth chopper circuit chops the pair of output signals received from the third chopper circuit according to a second clock signal different from the first clock signal, and outputs a pair of output signals. The second transconductance amplifier receives the pair of output signals from the fourth chopper circuit, and outputs a pair of differential output signals. The fifth chopper circuit has a pair of output terminals. The fifth chopper circuit chops the pair of differential output signals received from the second transconductance amplifier according to the second clock signal, and outputs a pair of output signals from the pair of output terminals. The first capacitor is connected between the pair of output terminals of the fifth chopper circuit. The third transconductance amplifier receives the pair of output signals from the fifth chopper circuit and outputs a pair of differential output signals. The low-pass filter suppresses ripple in the single-ended signal. The pair of differential output signals from the third transconductance amplifier are coupled to the pair of differential output signals from the first transconductance amplifier, respectively.

According to the first aspect, it is possible to suppress ripple due to the input offset voltage of the chopper amplifier, as well as ripple due to the input offset voltage of the second transconductance amplifier in the ripple attenuation loop.

According to a second aspect of the present disclosure, a power supply device includes an amplifier device and a feedback circuit. The feedback circuit returns a feedback signal back to the amplifier device. The feedback signal varies with an output signal of the amplifier device. The amplifier device includes a chopper amplifier, a ripple attenuation loop, a low-pass filter, and a buffer circuit. The chopper amplifier has a pair of input terminals and an output terminal. The low-pass filter is connected to the output terminal of the chopper amplifier. The low-pass filter receives an output signal of the chopper amplifier and output an output signal. The buffer circuit receives the output signal of the low-pass filter, and outputs an output signal. The chopper amplifier includes a first chopper circuit, a first transconductance amplifier, a second chopper circuit, and a converter. The first chopper circuit chops a pair of input signals received from the pair of input terminals according to a first clock signal, and outputs a pair of output signals. The first transconductance amplifier receives the pair of output signals from the first chopper circuit and outputs a pair of differential output signals. The second chopper circuit chops the pair of differential output signals received from the first transconductance amplifier according to the first clock signal, and outputs a pair of output signals. The converter receives the pair of output signals from the second chopper circuit as differential input signals, converts the received pair of output signals to a single-ended signal, and outputs the single-ended signal. The ripple attenuation loop includes a high-pass filter, a third chopper circuit, a fourth chopper circuit, a second transconductance amplifier, a fifth chopper circuit, a first capacitor, and a third transconductance amplifier. The high-pass filter receives the single-ended signal and outputs an output signal. The third chopper circuit chops the output signal received from the high-pass filter and a reference voltage according to the first clock signal, and outputs a pair of output signals. The fourth chopper circuit chops the pair of output signals received from the third chopper circuit according to a second clock signal different from the first clock signal and outputs a pair of output signals. The second transconductance amplifier receives the pair of output signals from the fourth chopper circuit and outputs a pair of differential output signals. The fifth chopper circuit has a pair of output terminals. The fifth chopper circuit chops the pair of differential output signals received from the second transconductance amplifier according to the second clock signal and outputs a pair of output signals from the pair of output terminals. The first capacitor is connected between the pair of output terminals of the fifth chopper circuit. The third transconductance amplifier receives the pair of output signals from the fifth chopper circuit and outputs a pair of differential output signals. The low-pass filter suppresses ripple in the single-ended signal. The pair of differential output signals from the third transconductance amplifier are coupled to the pair of differential output signals from the first transconductance amplifier, respectively.

According to the second aspect, it is possible to suppress ripple due to the input offset voltage of the chopper amplifier, as well as ripple due to the input offset voltage of the second transconductance amplifier in the ripple attenuation loop.

### First Embodiment

### Circuit Configuration of Amplifier Device

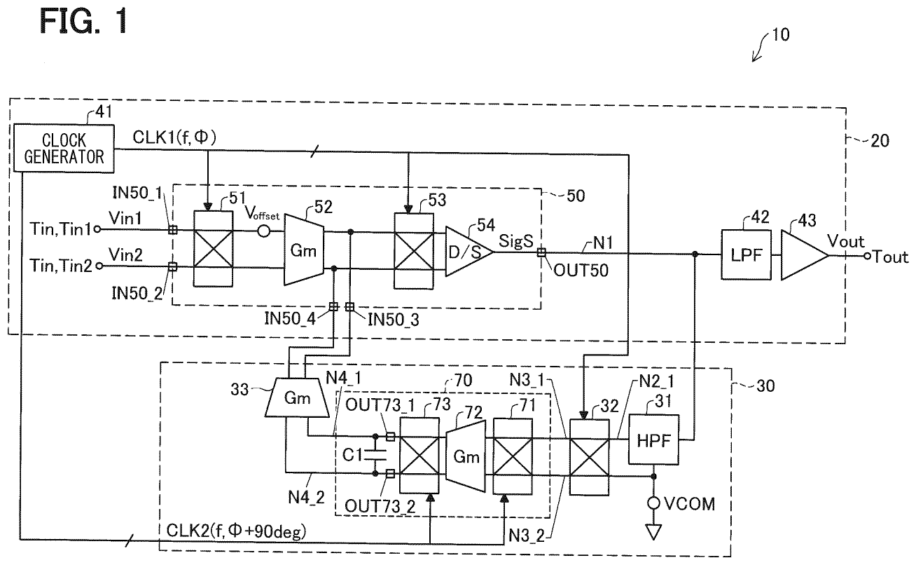

As shown in FIG. 1, an amplifier device 10 includes a pair of input terminals Tin, an output terminal Tout, a main signal path 20, and a ripple attenuation loop 30. The pair of input terminals Tin includes a first input terminal Tin1 and a second input terminal Tin2.

The main signal path 20 includes a chopper amplifier 50, a clock generator 41, a low-pass filter 42, and a buffer circuit 43. The chopper amplifier 50 includes a first input terminal IN50_1 and a second input terminal IN50_2 as a pair of input terminals, an output terminal OUT50, a first chopper circuit 51, a first transconductance amplifier 52, a second chopper circuit 53, and a converter 54.

The clock generator 41 generates a first clock signal CLK1 and a second clock signal CLK2, and outputs the generated first clock signal CLK1 and second clock signal CLK2. The first clock signal CLK1 is provided to the first chopper circuit 51, the second chopper circuit 53, and a third chopper circuit 32. The second clock signal CLK2 is provided to a fourth chopper circuit 71 and a fifth chopper circuit 73.

The first chopper circuit 51 has a pair of input terminals and a pair of output terminals. In the present application, “a pair of input terminals” specifically refers to two input terminals. Similarly, in the present application, “a pair of output terminals” specifically refers to two output terminals. One of the pair of input terminals of the first chopper circuit 51 receives the first input voltage Vin1. The other of the pair of input terminals of the first chopper circuit 51 receives the second input voltage Vin2. The first chopper circuit 51 chops the pair of input signals provided to the pair of input terminals in accordance with the first clock signal CLK1 and outputs a pair of output signals.

The first transconductance amplifier 52 is connected after the first chopper circuit 51. The first transconductance amplifier 52 has a pair of input terminals and a pair of output terminals. The pair of input terminals of the first transconductance amplifier 52 are connected to the pair of output terminals of the first chopper circuit 51, respectively. The first transconductance amplifier 52 receives, as input signals, the pair of output signals from the first chopper circuit 51 and outputs a pair of differential output signals.

The second chopper circuit 53 is connected after the first transconductance amplifier 52. The second chopper circuit 53 has a pair of input terminals and a pair of output terminals. Each of the pair of input terminals of the second chopper circuit 53 is connected to respective one of the pair of output terminals of the first transconductance amplifier 52. The second chopper circuit 53 chops the pair of differential output signals output from the first transconductance amplifier 52 according to the first clock signal CLK1, and outputs a pair of output signals.

The converter 54 is connected after the second chopper circuit 53. The converter 54 has a pair of input terminals and a single output terminal. The pair of input terminals of the converter 54 are connected to the pair of output terminals of the second chopper circuit 53, respectively. A pair of output signals output from the second chopper circuit 53 is provided to the converter 54 as differential inputs, which are converted into a single-ended signal SigS, and the converted single-ended signal SigS is output.

The low-pass filter 42 serves to suppress ripple in the single-ended signal SigS. In the present embodiment, the low-pass filter 42 is connected to the output terminal of the converter 54. The low-pass filter 42 receives the output signal from the chopper amplifier 50, attenuates high-frequency components, and passes signals within the low-frequency range.

The buffer circuit 43 is connected after the low-pass filter 42. The buffer circuit 43 receives the output signal from the low-pass filter 42. The buffer circuit 43 outputs the output signal.

The ripple attenuation loop 30 includes a high-pass filter 31, a third chopper circuit 32, an integrator 70, and a third transconductance amplifier 33. The high-pass filter 31 receives, as an input signal, the single-ended signal SigS and outputs an output signal.

The high-pass filter 31 is provided to remove the DC component from the single-ended signal SigS by high-pass filtering, thereby outputting only the AC component containing ripple. The third chopper circuit 32 is connected downstream of the high-pass filter 31 and has a pair of input terminals and a pair of output terminals. The output signal of the high-pass filter 31 is supplied to one input terminal of the third chopper circuit 32, while a reference voltage VCOM is supplied to the other input terminal. The third chopper circuit 32 chops both the output signal of the high-pass filter 31 and the reference voltage VCOM in accordance with a first clock signal CLK1, and outputs a pair of output signals.

The integrator 70 is connected after the third chopper circuit 32. The integrator 70 has a pair of input terminals and a pair of output terminals. The integrator 70 includes a fourth chopper circuit 71, a second transconductance amplifier 72, a fifth chopper circuit 73, and a first capacitor C1.

The fourth chopper circuit 71 has a pair of input terminals and a pair of output terminals. The pair of input terminals of the fourth chopper circuit 71 are connected to the pair of output terminals of the third chopper circuit 32, respectively. The fourth chopper circuit 71 chops the pair of output signals from the third chopper circuit 32 in accordance with the second clock signal CLK2 and outputs a pair of output signals.

The second transconductance amplifier 72 is connected after the fourth chopper circuit 71. The second transconductance amplifier 72 has a pair of input terminals and a pair of output terminals. The pair of input terminals of the second transconductance amplifier 72 is connected to the pair of output terminals of the fourth chopper circuit 71, respectively. The second transconductance amplifier 72 receives the pair of output signals from the fourth chopper circuit 71 and outputs a pair of differential output signals.

The fifth chopper circuit 73 is connected after the second transconductance amplifier 72. The fifth chopper circuit 73 has a pair of input terminals and a pair of output terminals. The pair of input terminals of the fifth chopper circuit 73 are connected to the pair of output terminals of the second transconductance amplifier 72, respectively. The fifth chopper circuit 73 chops the pair of differential output signals from the second transconductance amplifier 72 in accordance with the second clock signal CLK2 and outputs a pair of output signals. The pair of output terminals of the fifth chopper circuit 73 includes a first output terminal OUT73_1 and a second output terminal OUT73_2. The first capacitor C1 is connected between the pair of output terminals of the fifth chopper circuit 73, that is, between the first output terminal OUT73_1 and the second output terminal OUT73_2.

The third transconductance amplifier 33 is connected after the integrator 70. The third transconductance amplifier 33 has a pair of input terminals and a pair of output terminals. The pair of input terminals of the third transconductance amplifier 33 are connected to the pair of output terminals of the integrator 70, respectively. The third transconductance amplifier 33 receives, as input signals, a pair of output signals output from the integrator 70, and outputs a pair of differential output signals. The pair of differential output signals output from the third transconductance amplifier 33 are coupled to the pair of differential output signals output from the first transconductance amplifier 52, respectively.

### Circuit Details

The first chopper circuit 51, second chopper circuit 53, third chopper circuit 32, fourth chopper circuit 71, and fifth chopper circuit 73 have similar configurations. Accordingly, the configuration of the first chopper circuit 51 will be described as a representative example.

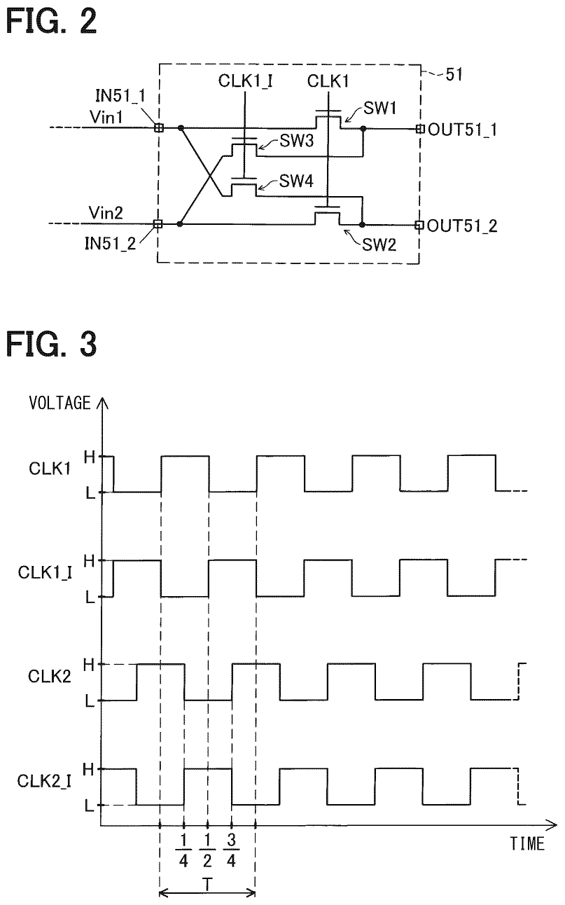

As shown in FIG. 2, the first chopper circuit 51 includes a first input terminal IN51_1, a second input terminal IN51_2, a first output terminal OUT51_1, a second output terminal OUT51_2, a first switch SW1, a second switch SW2, a third switch SW3, and a fourth switch SW4. In the present embodiment, N-channel MOSFETs are used for the first to fourth switches SW1 to SW4. However, the first to fourth switches SW1 to SW4 are not limited to N-channel MOSFETs and may alternatively be implemented using other types of switching elements.

The first switch SW1 has its source terminal connected to the first input terminal IN51_1 and its drain terminal connected to the first output terminal OUT51_1. The second switch SW2 has its source terminal connected to the second input terminal IN51_2 and its drain terminal connected to the second output terminal OUT51_2. The third switch SW3 has its source terminal connected to the second input terminal IN51_2 and its drain terminal connected to the first output terminal OUT51_1. The fourth switch SW4 has its source terminal connected to the first input terminal IN51_1 and its drain terminal connected to the second output terminal OUT51_2. The first clock signal CLK1 is provided to the gate terminals of both the first switch SW1 and the second switch SW2. The gate terminals of both the third switch SW3 and the fourth switch SW4 receive the first clock inversion signal CLK1_I, which is an inverted signal of the first clock signal CLK1.

As shown in FIG. 3, the first clock inversion signal CLK1_I is the inverted signal of the first clock signal CLK1. Similarly, the second clock inversion signal CLK2_I is the inverted signal of the second clock signal CLK2. In this embodiment, the first clock signal CLK1 and the second clock signal CLK2 have the same frequency but are out of phase with each other. Specifically, the phase difference between CLK1 and CLK2 is an odd multiple of 90 degrees. In this embodiment, the second clock signal CLK2 leads the first clock signal CLK1 by 90 degrees. Hereinafter, when no distinction is required among the first clock signal CLK1, the first clock inversion signal CLK1_I, the second clock signal CLK2, and the second clock inversion signal CLK2_I, they are collectively referred to as “clock signals.”

Although not shown in FIG. 1, in this embodiment, the clock generator 41 generates, in addition to the first clock signal CLK1 and the second clock signal CLK2, the first clock inversion signal CLK1_I and the second clock inversion signal CLK2_I, and outputs both CLK1_I and CLK2_I.

With reference to FIG. 2, the switches SW1 to SW4 are turned on while the corresponding clock signal is at a high level. Accordingly, when the first clock signal CLK1 is at a high level, the input signal from the first input terminal IN51_1 is applied to the first output terminal OUT51_1 through the first switch SW1, and the input signal from the second input terminal IN51_2 is applied to the second output terminal OUT51_2 through the second switch SW2. When the first clock signal CLK1 is at a low level, the input signal from the second input terminal IN51_2 is applied to the first output terminal OUT51_1 through the third switch SW3, and the input signal from the first input terminal IN51_1 is applied to the second output terminal OUT51_2 through the fourth switch SW4. In this manner, the first chopper circuit 51 modulates and outputs the first input voltage Vin1 and the second input voltage Vin2 in accordance with the first clock signal CLK1.

Unlike the first chopper circuit 51, the fourth chopper circuit 71 and the fifth chopper circuit 73 utilize the second clock signal CLK2 and the second inverted clock signal CLK2_I, instead of the first clock signal CLK1 and the first inverted clock signal CLK1_I.

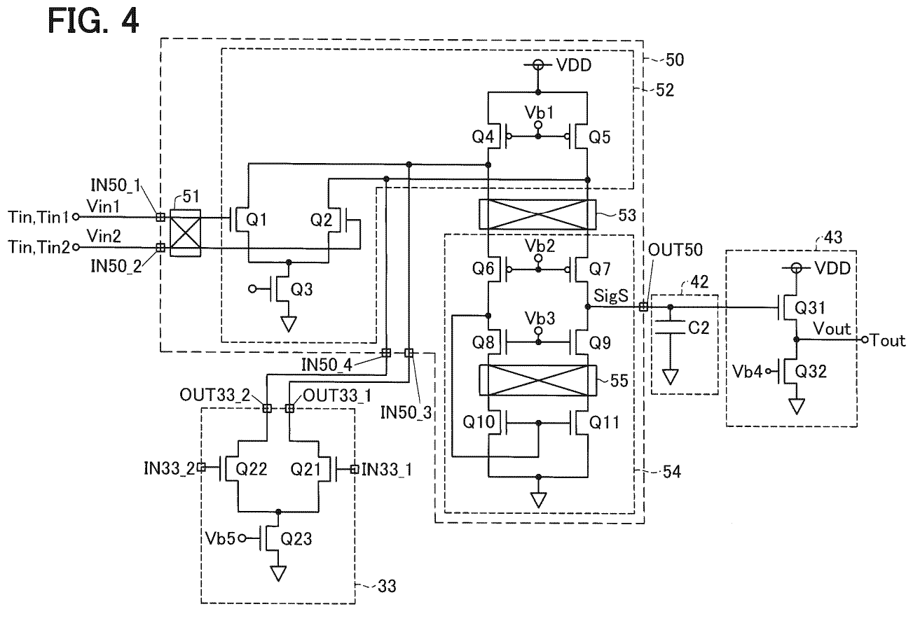

FIG. 4 shows a circuit diagram of the main signal path 20. In this embodiment, the folded-cascode type operational amplifier, as illustrated in FIG. 4, includes the first transconductance amplifier 52 and the converter 54.

The first transconductance amplifier 52 includes transistors Q1 through Q5. The converter 54 includes transistors Q6 through Q11 and a sixth chopper circuit 55. The transistors Q1 through Q3 and transistors Q8 through Q11 are N-channel MOSFETs. The transistors Q4 through Q7 are P-channel MOSFETs.

Transistor Q3 in the first transconductance amplifier 52 functions as a current source, while transistors Q1 and Q2 form a differential pair. Together, the transistors Q1 through Q3 form the input stage.

The sixth chopper circuit 55 of the converter 54 chops the pair of output signals from transistors Q8 and Q9 in accordance with the first clock signal CLK1, and outputs a pair of chopped signals.

The transistors Q4, Q6, Q8, and Q10 are connected in one cascode configuration, while the transistors Q5, Q7, Q9, and Q11 are connected in another cascode configuration. A bias voltage Vb1 is applied to the gate terminals of the transistors Q4 and Q5, while a bias voltage Vb2 is applied to the gate terminals of the transistors Q6 and Q7, and a bias voltage Vb3 is applied to the gate terminals of the transistors Q8 and Q9. The gate terminals of the transistors Q10 and Q11 are connected to the drain terminal of Q6. The transistors Q4 and Q5 serve as constant current sources, and the transistors Q8 to Q11 function as load stages. In the load stage, noise from the constant current sources can be reduced by chopping with the sixth chopper circuit 55.

The converter 54 functions as a gate-grounded amplifier stage and outputs a single-ended signal SigS, whose voltage varies in accordance with the differential output signal from the first transconductance amplifier 52.

In the present embodiment, the low-pass filter 42 has a capacitor C2 connected between the output terminal OUT50 of the chopper amplifier 50 and ground.

In the present embodiment, the buffer circuit 43 is a drain-grounded amplifier circuit comprising transistors Q31 and Q32, which are connected in series between a power supply (reference voltage VDD) and ground. Both Q31 and Q32 are N-channel MOSFETs. The single-ended signal SigS, after passing through the low-pass filter 42, is applied to the gate terminal of Q31. A bias voltage Vb4 is applied to the gate terminal of Q32.

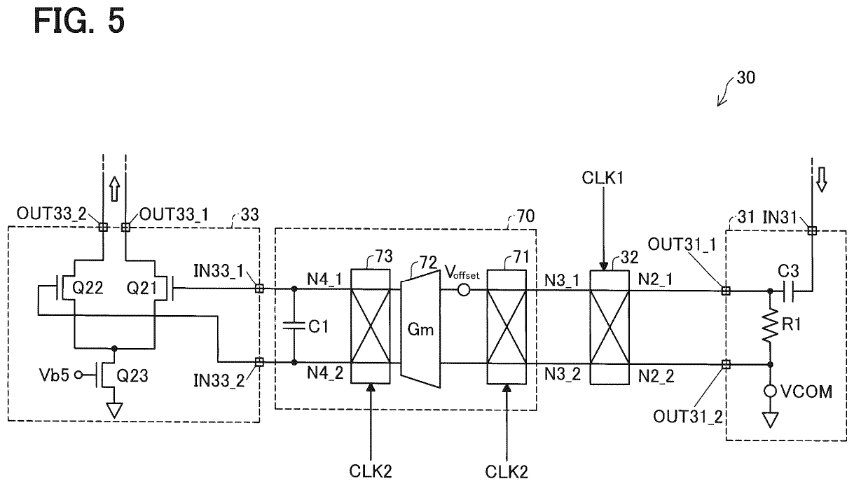

As shown in FIG. 5, the high-pass filter 31 includes an input terminal IN31, a first output terminal OUT31_1, a second output terminal OUT31_2, a resistor R1, and a capacitor C3. One terminal of the capacitor C3 is connected to the input terminal IN31, and the other terminal of the capacitor C3 is connected to the first output terminal OUT31_1. The resistor R1 is connected between the other terminal of the capacitor C3 and the reference voltage VCOM.

The third chopper circuit 32 and the integrator 70 are as described above. The third transconductance amplifier 33 includes a first input terminal IN33_1, a second input terminal IN33_2, a first output terminal OUT33_1, a second output terminal OUT33_2, and transistors Q21 through Q23. The transistors Q21 through Q23 are N-channel MOSFETs. The transistor Q23 functions as a current source. The transistors Q21 and Q22 function as a differential pair. As shown in FIG. 4, the first output terminal OUT33_1 of the third transconductance amplifier 33 is connected to the drain terminal of the transistor Q1 in the first transconductance amplifier 52. Furthermore, the second output terminal OUT33_2 of the third transconductance amplifier 33 is connected to the drain terminal of transistor Q2 in the first transconductance amplifier 52.

With this configuration, the amplifier device 10 can suppress ripple resulting from the input offset voltage generated in the first transconductance amplifier 52, as well as that generated in the second transconductance amplifier 72.

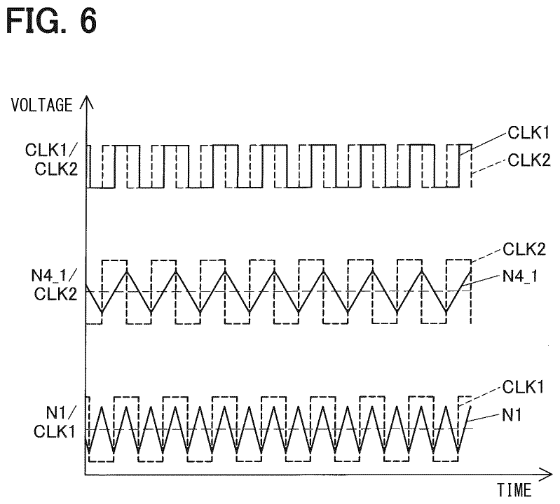

First, the suppression of ripple caused by the input offset voltage generated in the second transconductance amplifier 72 will be explained. FIG. 6 is a timing diagram that shows the clock signal and the respective voltage waveforms at nodes N4_1 and N1. As shown in FIG. 1, the node N1 is the connection point between the converter 54 and the low-pass filter 42. The node N4_1 is one of the two nodes connecting the fifth chopper circuit 73 and the third transconductance amplifier 33.

An example will be described in which an input offset voltage V_offset, as shown in FIG. 5, occurs in the second transconductance amplifier 72. Specifically, the following explanation will detail what kind of signal is provided to the main signal path 20 when a DC signal component, caused by the input offset voltage V_offset and output from the second transconductance amplifier 72, is supplied to the fifth chopper circuit 73. In the following description, the “DC signal component caused by the input offset voltage V_offset output from the second transconductance amplifier 72” will simply be referred to as the “output signal of the second transconductance amplifier 72.”

The output signal of the second transconductance amplifier 72 is chopped by the fifth chopper circuit 73 in accordance with the second clock signal CLK2. A current corresponding to the output signal output from the fifth chopper circuit 73 flows into the first capacitor C1. Accordingly, due to the phase delay caused by the first capacitor C1, the voltage waveform at the node N4_1, as shown in FIG. 6, becomes a triangular wave that lags by 90 degrees in phase with respect to the second clock signal CLK2. Since the first clock signal CLK1 lags the second clock signal CLK2 by 90 degrees in phase, the voltage waveform at node N4_1 is thus in phase with the first clock signal CLK1.

The third transconductance amplifier 33 amplifies the voltage difference of the input voltage and outputs the amplified voltage difference. The output signal of the third transconductance amplifier 33 is chopped by the second chopper circuit 53 in accordance with the first clock signal CLK1. Here, the phase of the first clock signal CLK1 is the same as the phase of the voltage waveform at the node N4_1. As a result, the apparent frequency of the voltage waveform at the node N1 becomes twice the frequency of the waveform prior to being processed by the second chopper circuit 53. The low-pass filter 42 is connected after the converter 54. Therefore, the ripple caused by the input offset voltage Voffset of the second transconductance amplifier 72 has an apparently higher frequency, and can thus be efficiently suppressed by the low-pass filter 42.

In this embodiment, the phase of the second clock signal CLK2 is advanced by 90 degrees relative to the first clock signal CLK1; however, the second clock signal CLK2 may instead be delayed by 90 degrees relative to the first clock signal CLK1. Furthermore, although the phase difference between the first clock signal CLK1 and the second clock signal CLK2 is 90 degrees, the phase difference is not limited to 90 degrees. A phase difference other than 90 degrees can also achieve ripple suppression effects. Since the ripple suppression effect is greater when the phase difference is an odd multiple of 90 degrees than when the phase difference is not an odd multiple of 90 degrees, it may be preferable that the phase difference be an odd multiple of 90 degrees.

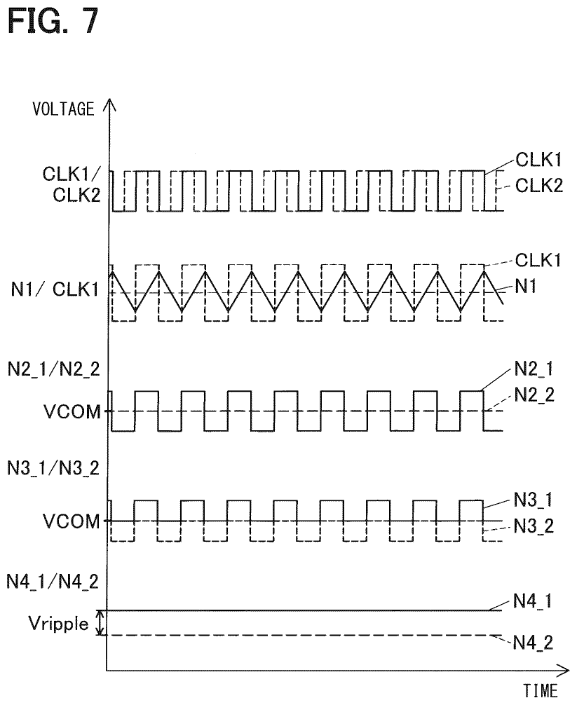

Next, the suppression of ripple caused by the input offset voltage generated in the first transconductance amplifier 52 will be explained. FIG. 7 is a timing diagram showing the clock signals and the respective voltage waveforms at the nodes N1, N2_1, N3_1, and N4_1. It should be noted that, as shown in FIG. 1, the node N2_1 is one of the two nodes that connect the high-pass filter 31 and the third chopper circuit 32. The node N3_1 is one of the two nodes that connect the third chopper circuit 32 and the fourth chopper circuit 71.

An example will be provided in which the input offset voltage Voffset, as shown in FIG. 1, is generated in the first transconductance amplifier 52. Specifically, an explanation will be given of how the DC signal component, resulting from the input offset voltage Voffset output by the first transconductance amplifier 52, is fed back to the main signal path 20 when it is provided to the second chopper circuit 53. In the following description, the “DC signal component resulting from the input offset voltage Voffset output by the first transconductance amplifier 52” will simply be referred to as the “output signal of the first transconductance amplifier 52.”

Here, the waveform of the output signal of the chopper amplifier 50 varies depending on the bandwidth of the chopper amplifier 50. Here, as typical examples, two cases will be described: a “first case” in which the output signal of the chopper amplifier 50 is sluggish with respect to the first clock signal CLK1 and a triangular wave is output, and a “second case” in which there is no sluggishness. First, the “first case” will be explained, in which the frequency of the first clock signal CLK1 is sufficiently higher than the output pole of the chopper amplifier 50, and the output signal of the chopper amplifier 50 becomes sluggish with respect to the first clock signal CLK1.

As shown in FIG. 7, in this “first case,” the voltage waveform at the node N1 is a triangular wave delayed by 90 degrees in phase with respect to the first clock signal CLK1.

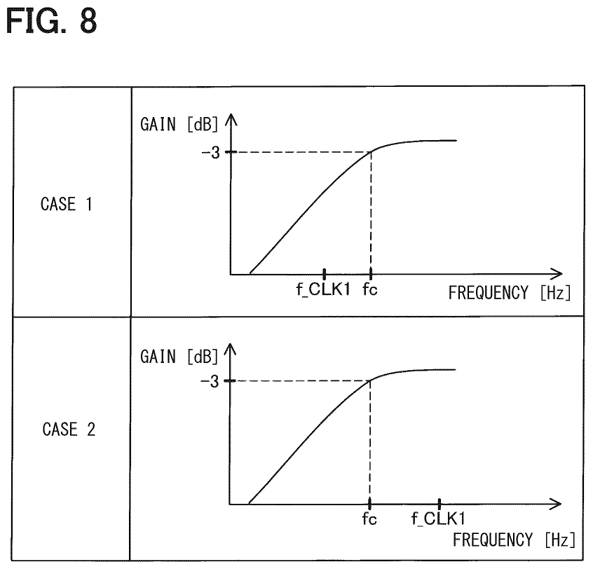

The high-pass filter 31 has a phase adjustment function for the input single-ended signal SigS with respect to the first clock signal CLK1. Specifically, the phase adjustment function of the high-pass filter 31 is exhibited by setting the cutoff frequency fc of the high-pass filter 31 to be different in the “first case” and the “second case.” FIG. 8 is a diagram illustrating the method for setting the cutoff frequency fc of the high-pass filter 31.

As shown in FIG. 8, in the “first case,” the parameters of the high-pass filter 31 are set so that the cutoff frequency fc of the high-pass filter 31 is higher than the frequency f_CLK1 of the first clock signal CLK1. On the other hand, in the “second case,” the parameters of the high-pass filter 31 are set so that the cutoff frequency fc of the high-pass filter 31 is lower than the frequency f_CLK1 of the first clock signal CLK1.

As shown in FIG. 7, in the “first case,” the cutoff frequency fc is set as described above, and due to the capacitor C3 included in the high-pass filter 31, the output at node N2_1 has a phase difference of zero with respect to the first clock signal CLK1.

The output signal from the high-pass filter 31 is chopped by the third chopper circuit 32 in accordance with the first clock signal CLK1. Therefore, as shown in FIG. 7, the voltage waveform at the node N3_1 appears on the high potential side relative to the reference voltage VCOM, while the voltage waveform at the node N3_2 appears on the low potential side relative to the reference voltage VCOM.

The output signal of the third chopper circuit 32 is integrated by the integrator 70. Therefore, as shown in FIG. 7, the voltages at the node N4_1 and the node N4_2 each become DC voltages. In addition, signals having other frequencies or phases are reduced by being averaged out by the integrator 70. The ripple voltage Vripple, which is the difference between the voltage at the node N4_1 and the voltage at the node N4_2, is converted into a DC current by the third transconductance amplifier 33.

As shown in FIG. 4, the output signal of the third transconductance amplifier 33 is provided to the first transconductance amplifier 52 so as to apply negative feedback. Therefore, as shown in the following equation (1), the current difference caused by the input offset voltage of the first transconductance amplifier 52 is canceled out.

$$Gm 1 \times Voffset - Gm 3 \times Vripple = 0 \qquad ( 1 )$$

In equation (1), “Gm1” is the transconductance value of the first transconductance amplifier 52. “Gm3” is the transconductance value of the third transconductance amplifier 33.

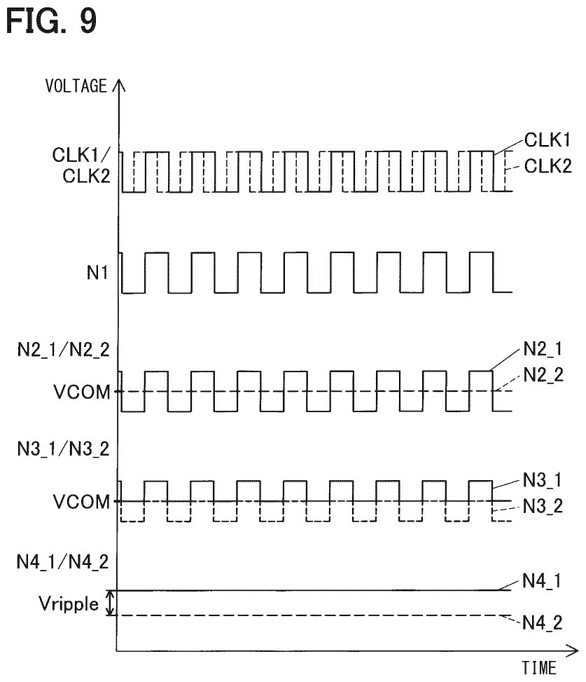

Next, the “second case” in which the output signal of the chopper amplifier 50 is not affected by the first clock signal CLK1 will be described. In this case, the phase does not change, and as shown in FIG. 9, the voltage waveform at the node N1 varies in accordance with the first clock signal CLK1.

As described above, since the cutoff frequency fc of the high-pass filter 31 is set lower than the frequency f_CLK1 of the first clock signal CLK1, the voltage waveform at the node N2_1 will be similar to the voltage waveform at the node N1. That is, the voltage waveform at the node N2_1 in the “second case” will be similar to the voltage waveform at the node N2_1 in the “first case.” Since the output signal after the integrator 70 is the same as in the “first case,” a detailed explanation is omitted. Also in the “second case,” the current difference caused by the input offset voltage of the first transconductance amplifier 52 is canceled out by the ripple attenuation loop 30.

According to the first embodiment described above, the amplifier device 10 includes the chopper amplifier 50 and the ripple attenuation loop 30. The chopper amplifier 50 includes the first chopper circuit 51, the first transconductance amplifier 52, the second chopper circuit 53, the converter 54, and the low-pass filter 42. The ripple attenuation loop 30 includes the high-pass filter 31, the third chopper circuit 32, the fourth chopper circuit 71, the second transconductance amplifier 72, the fifth chopper circuit 73, and the third transconductance amplifier 33. The pair of output signals output from the third transconductance amplifier 33 is coupled to the pair of output signals from the first transconductance amplifier 52, respectively. Ripple caused by the input offset voltage of the first transconductance amplifier 52 is converted into a DC signal by the ripple attenuation loop 30 and fed back to the chopper amplifier 50. As a result, ripple caused by the input offset voltage of the first transconductance amplifier 52 can be suppressed. In addition, the second clock signal CLK2 used in the ripple attenuation loop 30 is phase-shifted relative to the first clock signal CLK1 used in the chopper amplifier 50. Therefore, the apparent frequency of ripple caused by the input offset voltage of the second transconductance amplifier 72 can be increased. As a result, ripple caused by the input offset voltage of the second transconductance amplifier 72 can be efficiently suppressed by the low-pass filter 42.

In addition, the amplifier device 10 includes the clock generator 41 that outputs the first clock signal CLK1 and the second clock signal CLK2. The first clock signal CLK1 and the second clock signal CLK2 have the same frequency but different phases. Furthermore, the phase difference between the first clock signal CLK1 and the second clock signal CLK2 is an odd multiple of 90 degrees. As a result, the ripple suppression effect can be enhanced.

In addition, the low-pass filter 42 is connected to the output terminal of the chopper amplifier 50, receives the output signal of the chopper amplifier 50, and outputs a filtered signal. The amplifier device 10 includes the buffer circuit 43 that receives the output signal of the low-pass filter 42 and outputs a buffer signal. As a result, the amplifier device 10 can be provided.

### Second Embodiment

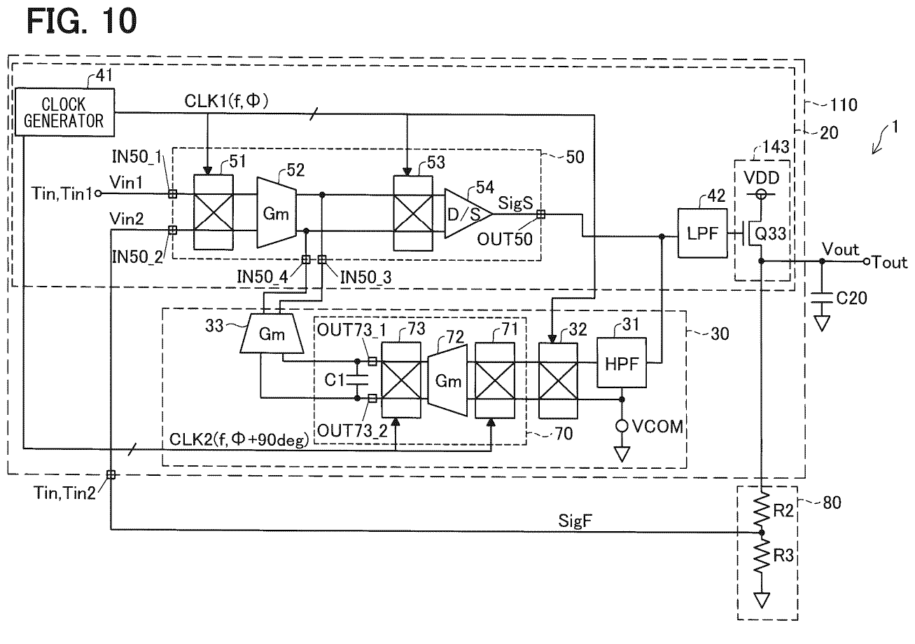

As shown in FIG. 10, the power supply device 1 includes an amplifier device 110, a feedback circuit 80, and a second capacitor C20. The amplifier device 110 according to the present embodiment differs from the amplifier device 10 described in the first embodiment in the circuit configuration of the buffer circuit 143. The components having the same configuration as in the first embodiment are designated by the same reference numerals, and detailed explanation thereof is omitted as appropriate.

The buffer circuit 143 according to the present embodiment includes a transistor Q33, which is an N-channel MOSFET. The output signal of the low-pass filter 42 is provided to the gate terminal of the transistor Q33. A power supply (reference voltage VDD) is connected to the drain terminal of the transistor Q33. The second capacitor C20 is connected between the output terminal Tout and ground.

The feedback circuit 80 returns a feedback signal SigF, corresponding to the output signal of the amplifier device 110, back to the amplifier device 110. The feedback circuit 80 includes resistors, namely resistor R2 and resistor R3. The resistor R2 and the resistor R3 are connected in series between the source terminal of transistor Q33 in the buffer circuit 143 and ground. The feedback circuit 80 uses a voltage-divided signal, generated by dividing the voltage of the output signal of the buffer circuit 143 using resistors R2 and R3, as the feedback signal SigF. Specifically, the connection node between the resistor R2 and the resistor R3 is connected to the second input terminal Tin2 of the amplifier device 110. The output voltage of the buffer circuit 143 is divided by resistors R2 and R3, and the voltage across resistor R3 is used as the feedback signal SigF.

A power supply reference voltage is provided to the first input terminal Tin1 of the amplifier device 110. The feedback signal SigF output from the feedback circuit 80 is provided to the second input terminal Tin2 of the amplifier device 110. With such a circuit configuration, the power supply device 1 functions as an LDO (Low Drop Out) regulator that steps down and outputs the reference voltage VDD. The output signal of the low-pass filter 42 is applied to the gate terminal of the transistor Q33. As described above, since the ripple is suppressed by the low-pass filter 42, the power supply device 1 is able to output a more stable voltage.

According to the second embodiment described above, since the power supply device 1 includes the amplifier device 110, it is possible to achieve the same effects as the first embodiment. In addition, the second capacitor C20 is connected to the output terminal Tout. Therefore, the second capacitor C20 functions as a bypass capacitor, enabling further stabilization of the output voltage of the power supply device 1.

Next, the other circuit configurations of each circuit will be described. The same reference numerals are assigned to components that are identical to those in the above embodiments, and detailed descriptions thereof will be omitted as appropriate.

### Other Configurations of Chopper Amplifier

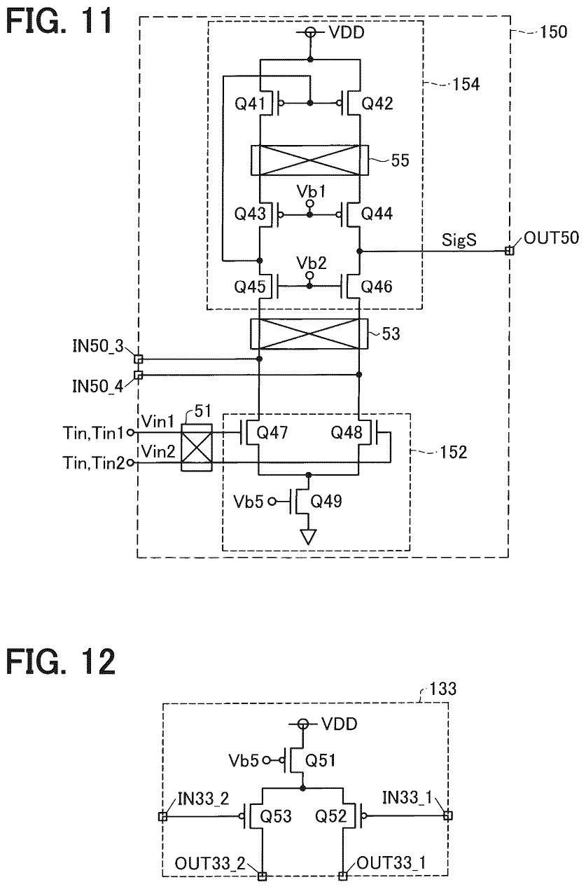

FIG. 11 is a diagram showing another configuration of the chopper amplifier 50. As shown in FIG. 11, a chopper amplifier 150 according to the present embodiment is configured such that a telescopic operational amplifier includes a first transconductance amplifier 152 and a converter 154.

The first transconductance amplifier 152 includes transistors Q47 to Q49. The converter 154 includes transistors Q41 to Q46 and a sixth chopper circuit 55. The transistors Q45 to Q49 are N-channel MOSFETs. The transistors Q41 to Q44 are P-channel MOSFETs.

The transistor Q49 of the first transconductance amplifier 152 functions as a current source. The transistors Q47 and Q48 function as a differential pair. The transistors Q47 to Q49 function as the input stage.

The sixth chopper circuit 55 chops the pair of output signals generated by transistors Q47 and Q48 in accordance with the first clock signal CLK1, and outputs a pair of chopped output signals. The transistors Q41, Q43, and Q45 are connected in one cascode configuration. The transistors Q42, Q44, and Q46 are connected in the other cascode configuration. A bias voltage Vb1 is applied to the gate terminals of both transistor Q43 and transistor Q44. A bias voltage Vb2 is applied to the gate terminals of both transistor Q45 and transistor Q46. The gate terminals of both transistor Q41 and transistor Q43 are connected to the drain terminal of the transistor Q43. The transistors Q41 through Q44 function as a load stage. The transistors Q41 and Q42 form a pair of loads. The chopper amplifier 150 according to the present embodiment can further reduce noise compared to the chopper amplifier 50 according to the preceding embodiment.

### Other Configurations of Third Transconductance Amplifier

FIG. 12 is a diagram showing another configuration of the third transconductance amplifier 33. As shown in FIG. 12, the third transconductance amplifier 133 according to the present embodiment includes transistors Q51 through Q53, which are P-channel MOSFETs. The transistor Q51 functions as a current source. The transistors Q52 and Q53 function as a differential pair.

### Other Configurations of Filter

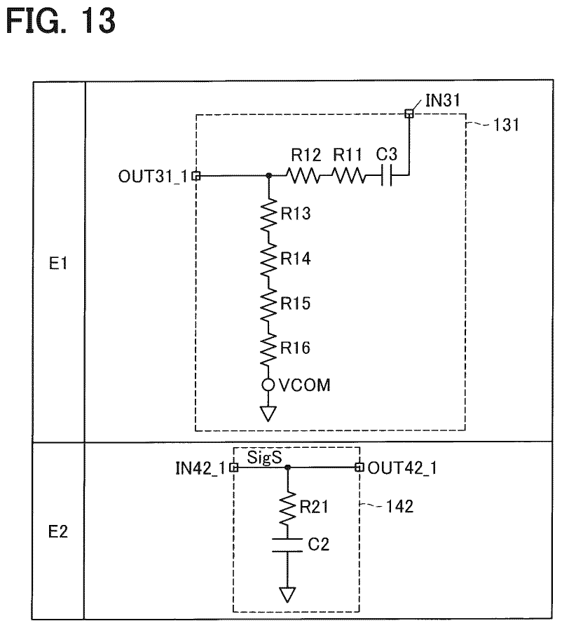

FIG. 13 is a diagram showing another configuration of the high-pass filter 31 and the low-pass filter 42. As shown in “E1” of FIG. 13, the high-pass filter 131 according to the present embodiment differs from the high-pass filter 31 according to the first embodiment in that the high-pass filter 131 includes multiple resistors.

The high-pass filter 131 includes a capacitor C3 and resistors R11 to R16, which are connected in series between the capacitor C3 and the reference voltage VCOM. An output line to a subsequent circuit is drawn from the connection node between the resistor R12 and the resistor R13. This allows the gain of the high-pass filter 131 to be adjusted. If the loop gain of the ripple attenuation loop 30 is too high, the output of the chopper amplifier 50 may become unstable. In such cases, according to the present embodiment, the gain can be adjusted, making it possible to stabilize the output of the chopper amplifier 50.

As shown as “E2” in FIG. 13, in the present embodiment, the low-pass filter 142 has a resistor R21 connected in series with the capacitor C2. This makes it possible to compensate for the frequency characteristics of the single-ended signal SigS.

### Other Configuration of Buffer Circuit

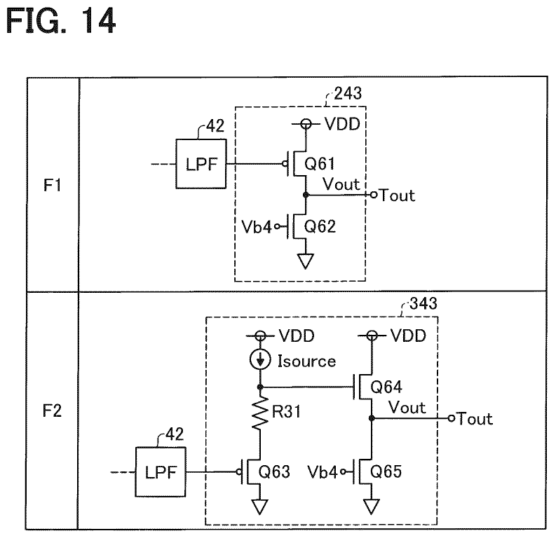

FIG. 14 is a diagram showing another configuration of the buffer circuit 43. As shown as “F1” in FIG. 14, the buffer circuit 243 of the present embodiment is a source-grounded amplifier circuit having a transistor Q61 and a transistor Q62 connected in series between the reference voltage VDD and ground. The transistor Q61 is a P-channel MOSFET, and the transistor Q62 is an N-channel MOSFET. The output signal of the low-pass filter 42 is provided to the gate terminal of transistor Q61. A bias voltage Vb4 is provided to the gate terminal of the transistor Q62. The output signal of the buffer circuit 243 is output from the connection node between the transistor Q61 and the transistor Q62.

As shown by “F2” in FIG. 14, the buffer circuit 343 according to the present embodiment includes a current source Isource, a resistor R31, a P-channel MOSFET transistor Q63, N-channel MOSFET transistors Q64 and Q65. The resistor R31 and the transistor Q63 are connected in series. The transistor Q64 and the transistor Q65 are connected in series between the reference voltage VDD and ground voltage. The output signal of the low-pass filter 42 is provided to the gate terminal of the transistor Q63. The connection node between the current source Isource and the resistor R31 is connected to the gate terminal of the transistor Q64. The output signal of buffer circuit 243 is output from the connection node between the transistor Q64 and the transistor Q65.

The buffer circuit 43 according to the first embodiment can suitably reduce the output resistance. The buffer circuit 243 according to the present embodiment can suitably increase the gain of the buffer circuit 243. Further, in cases where the supply voltage of the chopper amplifier 50 and the supply voltage of the buffer circuit 43 are different from each other, a level shift circuit for changing the voltage of the output signal of the chopper amplifier 50 may be added between the chopper amplifier 50 and the buffer circuit 43. The buffer circuit 343 according to the present embodiment functions as a buffer circuit including a level shift circuit.

### Other Configuration of Buffer Circuit and Feedback Circuit

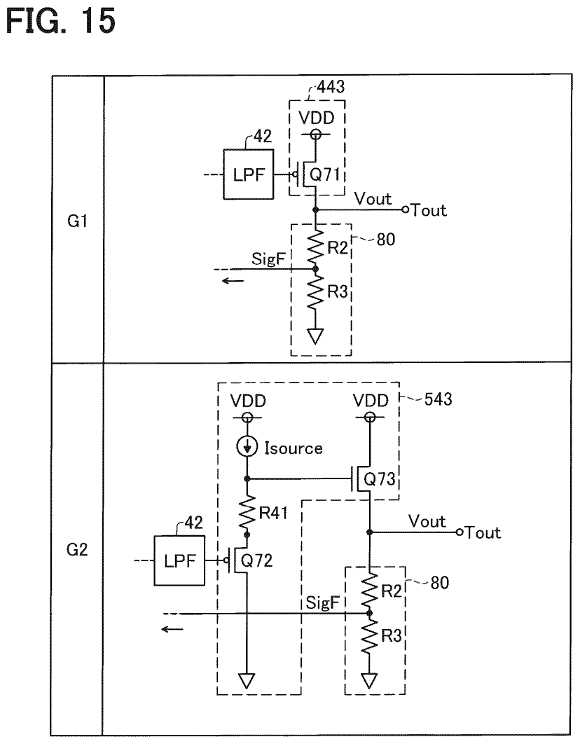

FIG. 15 is a diagram showing other configurations of the buffer circuit 143 and the feedback circuit 80 in the power supply device 1. As shown in “G1” of FIG. 15, the buffer circuit 443 according to the present embodiment is different from the buffer circuit 143 according to the second embodiment in that the transistor Q71 of a P-channel MOSFET is used instead of an N-channel MOSFET.

As shown in “G2” of FIG. 15, the buffer circuit 543 according to the present embodiment includes a current source Isource, a resistor R41, a transistor Q72 which is a P-channel MOSFET, and transistors Q72 and Q73 which are N-channel MOSFETs. The current source Isource, the resistor R41, and the transistor Q72 are connected in series. The output signal of the low-pass filter 42 is provided to the gate terminal of the transistor Q72. The connection node between the current source Isource and the resistor R41 is connected to the gate terminal of the transistor Q73. The output signal of the buffer circuit 543 is output from the connection node between the transistor Q73 and the feedback circuit 80.

### Other Embodiments

In the above first embodiment, the low-pass filter 42 is connected after the chopper amplifier 50, and the buffer circuit 43 is connected after the low-pass filter 42. However, the buffer circuit 43 may be connected after the chopper amplifier 50, and a low-pass filter 42 may be connected after the buffer circuit 43. Regardless of the position of the low-pass filter 42, ripple can be suppressed by providing the single signal SigS to the low-pass filter 42.

In the first embodiment, the transistors Q1 to Q3 of the first transconductance amplifier 52, which serves as the input stage of the chopper amplifier 50, are configured with N-channel MOSFETs, and the transistors Q8 to Q11, which serve as the load stage of the converter 54, are configured with P-channel MOSFETs. However, the input stage may be configured with P-channel MOSFETs and the load stage may be configured with N-channel MOSFETs. The same applies to the chopper amplifier 150.

In each of the above embodiments, each transistor in the respective circuits is either an N-channel MOSFET or a P-channel MOSFET. However, each transistor may also be another type of transistor, such as an IGBT.

The present disclosure is not limited to the above-described embodiments and modifications, but can be implemented in various configurations without departing from the spirit thereof. For example, the technical features in each embodiment corresponding to the technical features in the form described in the summary may be used to solve some or all of the above-described problems, or to provide one of the above-described effects. In order to achieve a part or all, replacement or combination can be appropriately performed. Further, unless a technical feature is described in this specification as being essential, it may be appropriately omitted.

What is claimed is:

1. An amplifier device comprising:
a chopper amplifier having
a pair of input terminals, and
an output terminal;
a ripple attenuation loop connected to the output terminal; and
a low-pass filter, wherein
the chopper amplifier includes:
a first chopper circuit configured to chop a pair of input signals received from the pair of input terminals according to a first clock signal, and output a pair of output signals;
a first transconductance amplifier configured to receive the pair of output signals from the first chopper circuit, and output a pair of differential output signals;
a second chopper circuit configured to chop the pair of differential output signals received from the first transconductance amplifier according to the first clock signal, and output a pair of output signals; and
a converter configured to
receive the pair of output signals from the second chopper circuit as differential input signals,
convert the differential input signals to a single-ended signal, and
output the single-ended signal,
the ripple attenuation loop includes:
a high-pass filter configured to receive the single-ended signal and output an output signal;
a third chopper circuit configured to chop the output signal received from the high-pass filter and a reference voltage according to the first clock signal, and output a pair of output signals;
a fourth chopper circuit configured to chop the pair of output signals received from the third chopper circuit according to a second clock signal, and output a pair of output signals, the second clock signal being different from the first clock signal;
a second transconductance amplifier configured to receive the pair of output signals from the fourth chopper circuit, and output a pair of differential output signals;
a fifth chopper circuit having a pair of output terminals, the fifth chopper circuit configured to chop the pair of differential output signals received from the second transconductance amplifier according to the second clock signal, and output a pair of output signals from the pair of output terminals;
a first capacitor connected between the pair of output terminals of the fifth chopper circuit; and
a third transconductance amplifier configured to receive the pair of output signals from the fifth chopper circuit, and output a pair of differential output signals,
the low-pass filter is configured to suppress ripple in the single-ended signal, and
the pair of differential output signals from the third transconductance amplifier are coupled to the pair of differential output signals from the first transconductance amplifier, respectively.

2. The amplifier device according to claim 1, further comprising:
a clock generator configured to output the first clock signal and the second clock signal, wherein
the first clock signal and the second clock signal have an identical frequency and different phases.

3. The amplifier device according to claim 2, wherein
a phase difference between the first clock signal and the second clock signal is an odd multiple of 90 degrees.

4. The amplifier device according to claim 1, wherein
the low-pass filter is connected to the output terminal of the chopper amplifier, and
the low-pass filter is configured to receive the output signal from the chopper amplifier and output an output signal, the amplifier device further comprising:
a buffer circuit is configured to receive the output signal from the low-pass filter and output an output signal.

5. The amplifier device according to claim 1, further comprising:
a buffer circuit connected to the output terminal of the chopper amplifier, the buffer circuit configured to receive the output signal from the chopper amplifier and output an output signal, wherein
the low-pass filter is configured to receive the output signal from the buffer circuit.

6. A power supply device comprising:
an amplifier device; and
a feedback circuit configured to return a feedback signal back to the amplifier device, the feedback signal being varied with an output signal of the amplifier device, wherein
the amplifier device includes:
a chopper amplifier having a pair of input terminals and an output terminal;
a ripple attenuation loop;
a low-pass filter connected to the output terminal of the chopper amplifier, the low-pass filter configured to receive the output signal from the chopper amplifier and output an output signal; and
a buffer circuit configured to receive the output signal from the low-pass filter and output an output signal,
the chopper amplifier includes:
a first chopper circuit configured to chop a pair of input signals received from the pair of input terminals according to a first clock signal and output a pair of output signals;
a first transconductance amplifier configured to receive the pair of output signals from the first chopper circuit and output a pair of differential output signals;
a second chopper circuit configured to chop the pair of differential output signals received from the first transconductance amplifier according to the first clock signal and output a pair of output signals; and
a converter configured to
receive the pair of output signals from the second chopper circuit as differential input signals,
convert the differential input signals to a single-ended signal, and
output the single-ended signal,
the ripple attenuation loop includes:
a high-pass filter configured to receive the single-ended signal and output an output signal;
a third chopper circuit configured to chop the output signal received from the high-pass filter and a reference voltage according to the first clock signal and output a pair of output signals;
a fourth chopper circuit configured to chop the pair of output signals received from the third chopper circuit according to a second clock signal and output a pair of output signals, the second clock signal being different from the first clock signal;
a second transconductance amplifier configured to receive the pair of output signals from the fourth chopper circuit and output a pair of differential output signals;
a fifth chopper circuit having a pair of output terminals, the fifth chopper circuit configured to chop the pair of differential output signals received from the second transconductance amplifier according to the second clock signal and output a pair of output signals from the pair of output terminals;
a first capacitor connected between the pair of output terminals of the fifth chopper circuit; and
a third transconductance amplifier configured to receive the pair of output signals from the fifth chopper circuit and output a pair of differential output signals,
the low-pass filter is configured to suppress ripple in the single-ended signal, and
the pair of differential output signals of the third transconductance amplifier are coupled to the pair of differential output signals of the first transconductance amplifier, respectively.

7. The power supply device according to claim 6, further comprising:
a clock generator configured to output the first clock signal and the second clock signal, wherein the first clock signal and the second clock signal have an identical frequency and different phases.

8. The power supply device according to claim 7,
a phase difference between the first clock signal and the second clock signal is an odd multiple of 90 degrees.

9. The power supply device according to claim 6, wherein
the feedback circuit is configured to receive the output signal from the buffer circuit,
the pair of input terminals includes a first input terminal and a second input terminal,
the first input terminal is configured to receive a power supply reference voltage, and
the second input terminal is configured to receive the feedback signal.

10. The power supply device according to claim 6, wherein
the feedback circuit is configured to receive the output signal from the buffer circuit, and
the feedback circuit includes a plurality of resistors, the feedback circuit configured to use a divided-voltage signal as the feedback signal, the divided-voltage signal being generated by dividing a voltage of the output signal of the buffer circuit using the plurality of resistors.

11. The power supply device according to claim 6, further comprising:
a second capacitor connected between the output terminal of the amplifier device and ground.
